(19) United States
(12) Patent Application Publication
(10) Pub. No.: US 2009/0114903 A1
(43) Pub. Date: May 7, 2009

(54) Integrated Nanotube and CMOS Devices For System-On-Chip (SoC) Applications and Method for Forming The Same

(76) Inventor: Amol M. Kalburge, Irvine, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 12/125,319

(22) Filed: May 22, 2008

Related U.S. Application Data
(60) Provisional application No. 60/940,343, filed on May 25, 2007.

(51) Int. Cl. H01L 29/775; H01L 21/4763

(52) U.S. Cl. 257/24; 438/586; 977/762; 257/E29.245; 257/E21.495

(57) ABSTRACT

An integrated, multilayer nanotube and complementary metal oxide semiconductor (CMOS) device is provided along with a method of forming the same. The device includes at least one CMOS device formed on at least one layer of the device, a first metal wiring layer that is electrically connected to the least one CMOS device, and at least one nanotube device formed over the first metal wiring layer in parasitic isolation from the at least one CMOS device. In one or more embodiments, the at least one CMOS device and the at least one nanotube device are located on different layers of a same semiconductor wafer chip to allow the wafer to be is used for system-on-chip (SoC) applications having RF/analog circuitry based on the least one nanotube device and digital circuitry based on the at least one CMOS device.

### RELATED APPLICATIONS

This application claims the benefit of and priority to U.S. Provisional Application Ser. No. 60/940,343, filed May 25, 2007, the contents of which are incorporated by reference herein in its entirety.

### TECHNICAL FIELD

This disclosure relates generally to system-on-chip (SoC) applications and, more particularly, to a method for integrating carbon nanotube (CNT) devices with complementary metal oxide semiconductor (CMOS) process technology on the same wafer.

### BACKGROUND

One of the challenges facing broad commercialization of nanotube technology is the lack of a clear path for integrating carbon nanotubes (CNTs) with standard CMOS devices. There have been prior attempts to use nanoelectromechanical switches (NEMS) for non-volatile memory applications where such nanotube-based NEMS devices were fabricated in a silicon manufacturing plant using standard fabrication equipment. However, such prior silicon fabrication approaches of manufacturing NEMS or CNT-based switches did not integrate CNT devices with silicon CMOS devices on the same wafer.

There have also been attempts at integrating nanotube FETs with nMOS (n-channel metal oxide semiconductor) technology. However, such integration techniques with nMOS processes deviated from standard CMOS processes having both nMOS and pMOS (p-channel metal oxide semiconductor) regions and required deep poly backside gate contacts and buried, under-oxide, source/drain regions. Such techniques for integrating CNT devices with an nMOS flow were uniquely tailored to CNT device fabrication and quite different from the standard CMOS process technology.

### SUMMARY

According to a feature of the disclosure, a method is provided for integrating nanotube devices with a standard CMOS process flow to integrate nanotube devices with complementary metal oxide semiconductor (CMOS) devices on the same wafer.

In one or more embodiments, an integrated, multilayer nanotube and complementary metal oxide semiconductor (CMOS) device is provided along with a method of forming the same. The device includes at least one CMOS device formed on at least one layer of the device, a first metal wiring layer that is electrically connected to the least one CMOS device, and at least one nanotube device formed over the first metal wiring layer in parasitic isolation from the at least one CMOS device. In one or more embodiments, the at least one CMOS device and the at least one nanotube device are located on different layers of a same semiconductor wafer chip to allow the wafer to be is used for system-on-chip (SoC) applications having RF/analog circuitry based on the least one nanotube device and digital circuitry based on the at least one CMOS device.

In one or more embodiments, the integrated nanotube/CMOS device includes at least one CMOS device having an NFET device and a PFET device formed in a silicon substrate layer with each of the NFET and PFET devices including gate electrodes formed over a portion of the silicon substrate. A first dielectric layer is formed over the NFET and PFET devices and the gate electrodes. Contacts are formed to extend through the first dielectric layer to electrically connect the gate electrodes of the NFET and PFET devices to the first metal wiring layer, where a second dielectric layer is formed over the first metal wiring layer. In one or more embodiments, the integrated nanotube and CMOS device further includes at least one nanotube device comprising a carbon nanotube FET formed over the second dielectric barrier layer. An inter-metal dielectric layer is formed over the carbon nanotube FET and a portion of the second dielectric layer covering the CMOS device. A third dielectric layer is formed over the inter-metal dielectric layer, and metallic contacts are formed in vias extending through the third dielectric layer and the inter-metal dielectric layer to: (i) the first metal wiring layer, (ii) the nanotube gate of each carbon nanotube FET, and (iii) source and drain areas of each carbon nanotube FET. A second metal wiring layer is formed including portions that are electrically connected to corresponding metallic contacts formed in the vias.

### DRAWINGS

The above-mentioned features and objects of the present disclosure will become more apparent with reference to the following description taken in conjunction with the accompanying drawings wherein like reference numerals denote like elements and in which:

FIGS. 1-10 illustrate cross-sectional views of various stages a method of integrating nanotube devices with a standard CMOS process flow to integrate nanotube devices with CMOS devices on the same wafer for system-on-chip (SoC) applications in accordance with one or more embodiments of the present disclosure.

### DETAILED DESCRIPTION

The present disclosure is directed to a method for integrating nanotube devices with a standard complementary metal oxide semiconductor (CMOS) process flow to integrate the formation of nanotube devices with CMOS devices on different layers in parasitic isolation from one another on the same wafer for system-on-chip (SoC) applications.

In one or more embodiments described herein, for ease of description, nanotube devices may be described as carbon nanotubes (CNTs), while it is understood that the nanotube devices may comprise any type of nanotubes, including but not limited to carbon nanotubes (CNTs), single walled nanotubes (SWNTS) and multiwalled nanotubes (MWNTs). Further, each of the various embodiments could also be implemented in any 1-D semiconductor device (e.g., nanotubes, nanowires, etc.) or 2-D semiconductor device (e.g., graphene-based devices, etc.).

In one or more embodiments, the formation of the nanotube devices is integrated into CMOS back end processing, thereby eliminating the risk of contamination to critical CMOS devices in the front end processing. Further, by integrating the nanotube device formation in the back end processing, nanotube devices are protected from the high thermal budget steps associated with CMOS front end processes. Still further, in one or more embodiment, by separating nanotube devices away from the silicon substrate containing the CMOS devices, parasitic capacitance between nanotube devices and CMOS devices in the silicon substrate is minimized, thus allowing for higher performance nanotube devices.

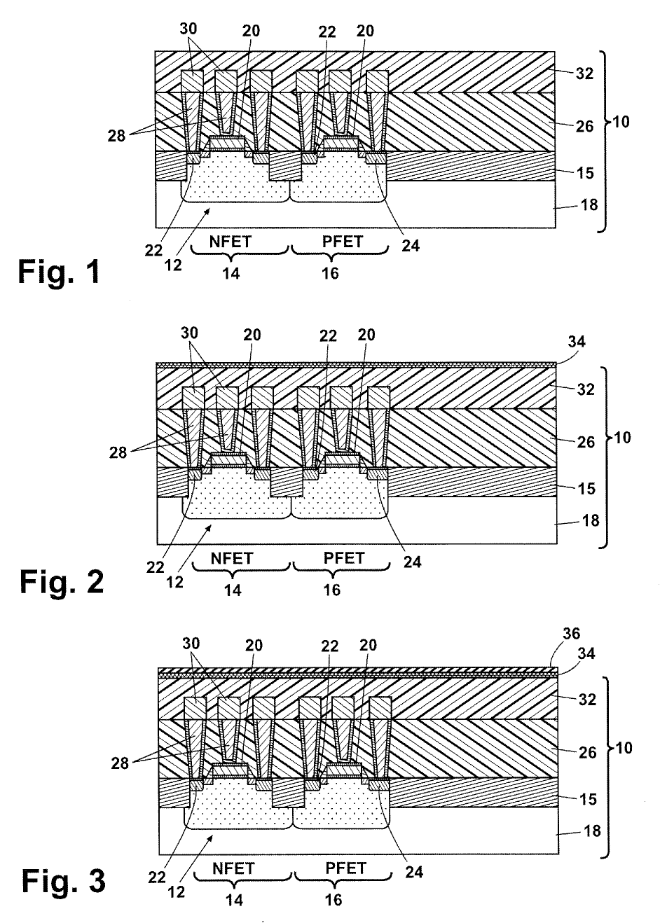

Referring now to FIGS. 1-10, cross-sectional views of various stages of a method of integrating nanotube devices with a back end CMOS process flow to integrate the formation of nanotube devices with CMOS devices on different layers of the same wafer are illustrated in accordance with one or more embodiments of the present disclosure. Initially, as illustrated in FIG. 1, a CMOS wafer 10 having at least one CMOS device 12 is formed using any standard CMOS process known to those skilled in the art. In one or more embodiments, the CMOS wafer 10 includes at least one CMOS device 12 including a NFET device 14 and a PFET device 16 formed in a p-type silicon (P—Si) wafer 18. The CMOS wafer 10 is etched with an oxide 15 deposited in the etched areas, Gate electrodes 20 are formed over the silicon substrate 18 for each of the NFET device 14 and the PFET device 16. Each of the NFET device 14 and the PFET device 16 include source 22 and drain 24 regions. A pre-metallic dielectric (PMD) layer 26 is formed to extend over the NFET and PFET devices 14 and 16 in the substrate 18 and the gate electrodes 22. In one or more embodiments, PMD layer 26 may comprise silicon oxide, silicon oxynitride, or any suitable low-k dielectric material. Contacts holes are etched through the PMD layer 26 and then are filled with electrically conductive materials 28 (e.g. Ti, TiN, W) to electrically connect the gate electrodes 20 and source 22 and drain 24 regions of the NFET device 14 and the PFET device 16 to a patterned first metal wiring layer 30. An inter-metallic dielectric (IMD) layer 32 is formed over the first metal wiring layer 30. In one or more embodiments, IMD layer 32 may comprise silicon oxide, silicon oxynitride, or any suitable low-k dielectric material.

In one or more embodiments, the integrated nanotube/CMOS device further includes at least one nanotube device that is formed spaced away from the substrate 18 to minimize the parasitic capacitance between the nanotubes device and the CMOS device 12 on the substrate 18, thus allowing for higher performance nanotube devices.

In one or more embodiments, a layer of nanotubes 34 (e.g., CNTs) is deposited on the IMD layer 32 using an appropriate nanotube synthesis technique, as illustrated in FIG. 2. A nanotube gate dielectric layer 36 is then deposited over the nanotubes 34, as illustrated in FIG. 3. The nanotube gate dielectric layer 36 serves at least one and possibly all of the following purposes (i) acting as a gate dielectric under gates for nanotube devices acting as FETs, (ii) acting as a passivation layer elsewhere, and (iii) acting as an etch stop for protecting the nanotubes 34 during various subsequent removal etching procedures. Any suitable deposition method may be employed including but not limited to atomic layer deposition (ALD) of the nanotube gate dielectric layer 36. Examples of such gate dielectric layer 36 are aluminum oxide (Al₂O₃), hafnium oxide (HfO₂), zirconium oxide (ZrO₂), silicon nitride (SiₓN_{y}).

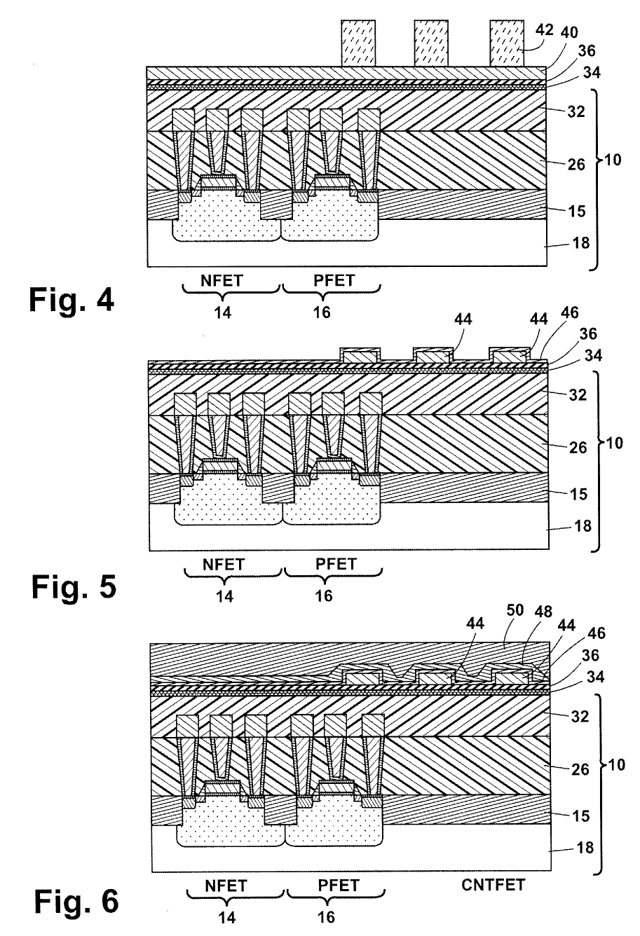

In one or more embodiments, a gate electrode layer 40 (e.g., a metal such as aluminum or any other conducting material known to those skilled in the art in the formation of gates) is then deposited over the nanotube gate dielectric layer 36 and patterned with a photoresist material 42, as illustrated in FIG. 4. The nanotube gate dielectric layer 36 is then selectively etched to form the patterned nanotube gates 44, where the etching is selectively stopped at the nanotube gate dielectric layer 36. The photoresist material 42 is then removed and a thin liner material 46 (e.g., SiN, silicon oxinitride or the like) is deposited over the nanotube gates 44 and nanotube gate dielectric layer 36 to serve as a via etch stop during subsequent via formation procedures, as illustrated in FIG. 5.

Referring to FIG. 6, in one or more embodiments, a layer of inter-metal dielectric (IMD) material 48 is then deposited over the liner material 46, followed by the deposition of another inter-metallic dielectric (IMD) layer 50 (e.g., an oxide layer or the like), where a chemical mechanical polishing (CMP) step or other smoothing/polishing technique is performed subsequently to polish the surface of the IMD layer 50.

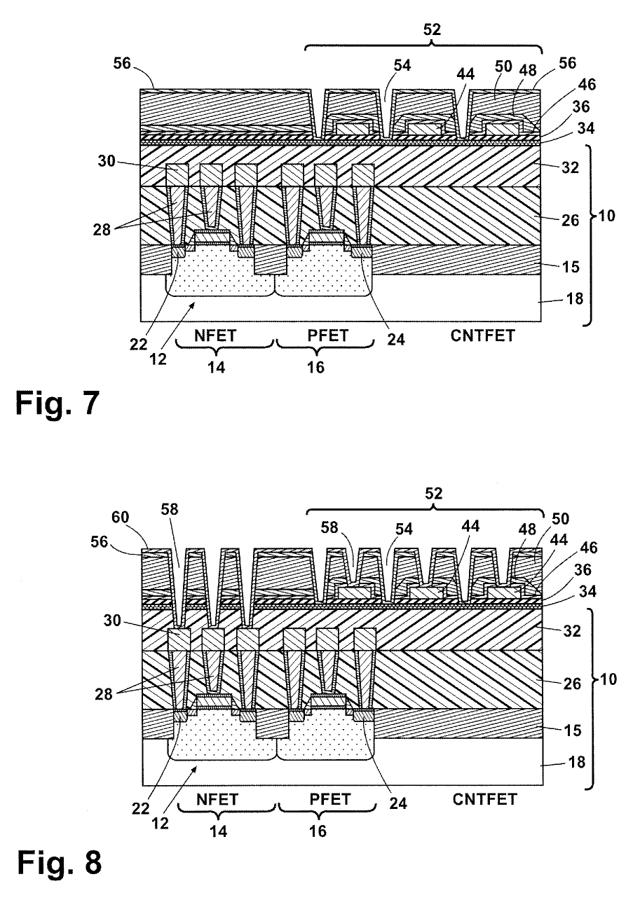

In one or more embodiments, at least one nanotube device 52 is formed over the IMD layer 32. In one or more embodiments, the at least one nanotube device includes at least one carbon nanotube field effect transistor (CNT FET). Contact holes or vias 54 are then etched or otherwise formed in the IMD layers 48 and 50. The nanotube gate dielectric layer 36 is then selectively removed from the base of the via hole 54 to expose portions of the layer of nanotubes 34 serving as source and drain regions of each of the CNT FETs 52. In one or more embodiments, a layer of Palladium (Pd) 56 or another similar contact metal is then deposited on the surface of the structure so that it also extends within via hole 54 to form ohmic contacts to the layer of nanotubes 34, as illustrated in FIG. 7.

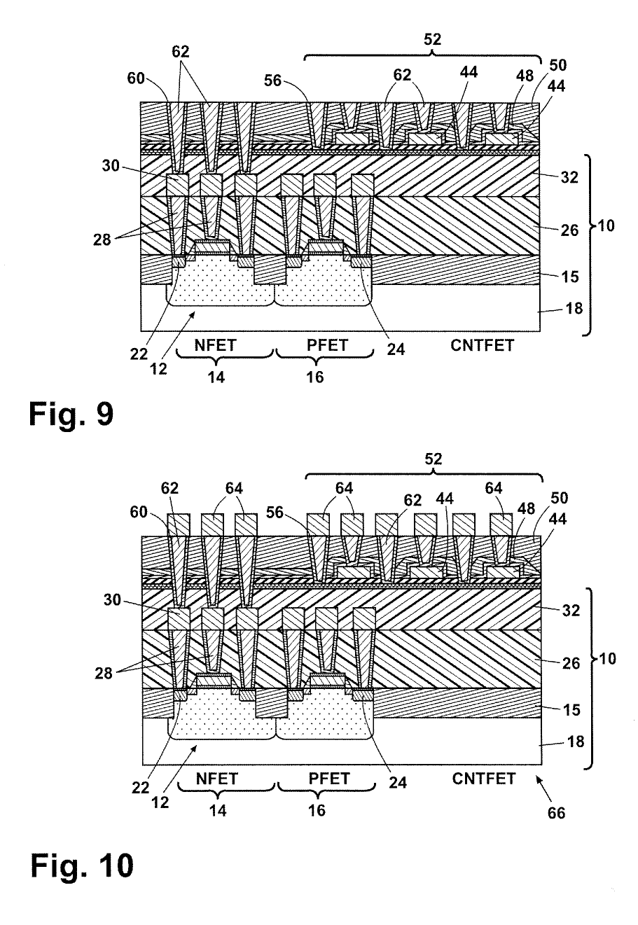

In one or more embodiments, contact holes or vias 58 are further etched or otherwise formed in the IMD layers 50, 48 and/or 32 and the liner material 46 to the first metal wiring layer 30 for the CMOS devices 12 and exposed portions of the nanotube gates 44 for the CNT FETs 52. A layer of CMOS contact liner stack material 60 known to those skilled in the art (e.g., Ti, TiN, W, or other known liner stack material) is then deposited over the surface of the structure so as to also line the surface of the via holes 58, as illustrated in FIG. 8. In one or more embodiments, a metal contact material 62 (e.g., tungsten 62 or other similar metal contact material) is then deposited so as to fill the via holes 58. CMP or other smoothing/polishing steps are performed until the CMOS contact liner stack material 60 is removed from the upper surface of the barrier layer 50 while leaving the via holes 58 lined with CMOS contact liner stack material 60 and filled with metal contact material 62, as illustrated in FIG. 9. A second patterned metal wiring layer 64 is formed including portions that are electrically connected to corresponding metallic contacts 62 formed in the via holes 58, as illustrated in FIG. 10.

In this manner, an integrated, multilayer nanotube and complementary metal oxide semiconductor (CMOS) device 66, as illustrated in FIG. 10, is provided including at least one nanotube device 52 formed over the first metallic contact layer in parasitic isolation from the at least one CMOS device 12 formed on a different layer of the device 66, thereby minimizing the parasitic capacitance between the nanotube device 52 and the CMOS device 12. In this manner, a single semiconductor wafer chip can be used for system-on-chip (SoC) applications wherein the chip include RF/analog circuitry based on the least one nanotube device and digital circuitry based on the at least one CMOS device. Additional standard back end CMOS processes can then continue to be performed on the integrated nanotube/CMOS device 66 illustrated in FIG. 10.

As can be seen from the foregoing, a integrated nanotube/CMOS device and method for forming the same are provided that allow nanotube devices acting as FETs to be integrated in a back end of a standard CMOS process flow with no risk of metal contamination to CMOS circuitry formed on the wafer with the nanotube devices or to front end CMOS fabrication equipment.

While the system and method have been described in terms of what are presently considered to be specific embodiments, the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. An integrated, multilayer nanotube and complementary metal oxide semiconductor (CMOS) device, comprising:
at least one CMOS device formed on at least one layer of the device;
at least one metal wiring layer that is electrically connected to the least one CMOS device;
at least one nanotube device formed over the metal wiring layer in parasitic isolation from the at least one CMOS device.

2. The device of claim 1, wherein the at least one CMOS device and the at least one nanotube device are located on different layers of a same semiconductor wafer chip.

3. The device of claim 1, wherein the wafer chip is used for system-on-chip (SoC) applications having RF/analog circuitry based on the least one nanotube device and digital circuitry based on the at least one CMOS device.

4. The device of claim 1, wherein the at least one CMOS device comprises:
an NFET device and a PFET device formed in a silicon substrate layer with each of the NFET and PFET devices including gate electrodes formed over the silicon substrate.

5. The device of claim 4, further comprising:
a first dielectric layer formed over the NFET and PFET devices and gate electrodes;
contacts formed to extend through the first dielectric layer electrically connecting the gate electrodes of the NFET and PFET to the metal wiring layer; and
a second dielectric layer formed over the metal wiring layer.

6. The device of claim 5, wherein the at least one nanotube device includes at least one carbon nanotube FET formed over the second dielectric layer.

7. The device of claim 6, further comprising:
an inter-metal dielectric layer formed over the carbon nanotube FET and a portion of the second dielectric layer covering the at least one CMOS device; and
a third dielectric layer formed over the inter-metal dielectric layer.

8. The device of claim 7, wherein each of the at least one carbon nanotube FET includes a nanotube gate and source and drain areas, the device further comprising:
metallic contacts formed in vias formed through the third dielectric layer and the inter-metal dielectric layer to the metal wiring layer, the nanotube gate of each carbon nanotube FET, and source and drain areas of each carbon nanotube FET; and
a second metal wiring layer including portions that are electrically connected to corresponding metallic contacts formed in the vias.

9. A method, comprising:
forming at least one complementary metal oxide semiconductor (CMOS) device on a semiconductor substrate;
forming a first metal wiring layer that is electrically connected to the least one CMOS device;
forming a first inter-metallic dielectric (IMD) layer over the first metal wiring layer;
forming at least one nanotube device over the dielectric layer in parasitic isolation from the at least one CMOS device.

10. The method of claim 9, further comprising:
forming each CMOS device by forming an NFET device and a PFET device in a silicon substrate layer with each of the NFET and PFET devices including gate electrodes formed over the silicon substrate;
forming a pre-metallic dielectric (PMD) layer over the NFET and PFET devices and gate electrodes, wherein the first metal wiring layer is formed over the PMD layer; and
forming contacts to extend through the PMD layer to electrically connect the gate electrodes of the NFET and PFET to the first metal wiring layer.

11. The method of claim 10, wherein the at least one nanotube device includes at least one carbon nanotube FET formed over the first IMD layer with each carbon nanotube FET including a nanotube gate and source and drain areas, the method further comprising:
forming a second inter-metal dielectric (IMD) layer over the carbon nanotube FET and a portion of the first IMD layer covering the at least one CMOS device;
forming a third inter-metal dielectric (IMD) layer over the second IMD layer;
forming vias through the third IMD layer and the second IMD layer to the first metal wiring layer, to the nanotube gate of each carbon nanotube FET, and to the source and drain areas of each carbon nanotube FET;
forming metallic contacts in each of the vias;
forming a second metal wiring layer including portions that are electrically connected to corresponding metallic contacts formed in the vias.

12. The method of claim 11, wherein the at least one carbon nanotube FET is formed by:
forming a layer of nanotubes over the first IMD layer;
forming a layer of nanotube gate dielectric material over the layer of nanotubes;
forming a nanotube gate electrodes over the nanotube gate dielectric material;
forming a liner material resistant to etching over the nanotube gate electrodes and nanotube gate dielectric material;
forming the second IMD layer over the liner material; and
forming the third IMD layer over the second IMD layer.

13. The method of claim 4, wherein the nanotube gate electric material serves as an etch stop for protecting the nanotubes during various removal procedures.

14. The method of claim 9, further comprising integrating the formation of the at least one nanotube device into a back end process of a CMOS process flow to integrate the formation of nanotube and CMOS devices into the same CMOS process flow.

15. The method of claim 9, further comprising forming integrated nanotube and CMOS devices on the same substrate for system-on-chip (SoC) applications having RF/analog circuitry based on nanotube devices and digital circuitry based on CMOS devices.

16. The method of claim 9, further comprising forming the at least one nanotube devices as at least one carbon nanotube FET.
